(19) United States
(12) Patent Application Publication
(10) Pub. No.: US 2026/0214925 A1
(43) Pub. Date: Jul. 23, 2026

(54) TRENCH MOSFET WITH BOTTOM OXIDE THICKNESS EQUAL TO OR GREATER THAN SIDEWALL OXIDE THICKNESS

(71) Applicant: Microchip Technology Incorporated, Chandler, AZ (US)

(72) Inventors: Shesh Mani Pandey, Gilbert, AZ (US); Sami Alexandre El Hageali, Castle Rock, CO (US); Bruce Odekirk, Portland, OR (US); Michael Don Whiteman, Woodland Park, CO (US)

(73) Assignee: Microchip Technology Incorporated, Chandler, AZ (US)

(21) Appl. No.: 19/207,209

(22) Filed: May 13, 2025

Related U.S. Application Data
(60) Provisional application No. 63/747,267, filed on Jan. 20, 2025.

(51) Int. Cl. H10D 30/01; H10D 30/66; H10D 62/832

(52) U.S. Cl. CPC H10D 30/0297; H10D 30/668; H10D 62/8325

(57) ABSTRACT

A trench MOSFET with a trench bottom oxide thickness that is equal to or greater than a trench sidewall oxide thickness, and a method of making the same. A trench, including a sidewall and a bottom, is created in a semiconductor material. A first bottom thickness of a gate oxide is deposited on the bottom, and a first sidewall thickness of the gate oxide is deposited on the sidewall. The first sidewall thickness is removed, leaving the first bottom thickness. A second sidewall thickness is grown on the sidewall of the trench, and a second bottom thickness is grown on top of the first bottom thickness. The first and second bottom thicknesses of the gate oxide form a total bottom thickness that is at least equal to the second sidewall thickness, and may be between one (1) and two (2) times greater than the second sidewall thickness.

### RELATED APPLICATION

The present U.S. non-provisional patent application is related to and claims priority benefit of an earlier-filed U.S. provisional patent application titled “Trench MOSFET with Two Different Oxide Thicknesses at Sidewall and Bottom of Trench,” Ser. No. 63/747,267, filed Jan. 20, 2025. The entire content of the identified earlier-filed application is incorporated by reference as if fully set forth herein.

### FIELD

The present disclosure relates to metal oxide semiconductor field-effect transistors and methods of making them, and more particularly, the various examples described herein concern a trench metal oxide semiconductor field-effect transistor with a trench bottom oxide thickness that is equal to or greater than a trench sidewall oxide thickness. The present disclosure also relates to a method of making a trench metal oxide semiconductor field-effect transistor with a trench bottom oxide thickness that is equal to or greater than a trench sidewall oxide thickness.

### BACKGROUND

A metal-oxide-semiconductor field-effect transistor (MOSFET) is an active, voltage-controlled semiconductor device, in which varying an electrical voltage between a gate and a body controls an electrical current flowing through a semiconductor channel between a drain and a source. Applications for MOSFETs include amplifiers, switches, resistors, regulators, oscillators, and choppers. It is generally desirable to improve the performance and reduce the cost of MOSFETs, but it can be difficult to do so.

This background discussion is intended to provide related information, and is not necessarily prior art.

### SUMMARY

Examples provide a trench MOSFET with a trench bottom oxide thickness that is equal to or greater than a trench sidewall oxide thickness, and a method of making a trench MOSFET with a trench bottom oxide thickness that is equal to or greater than a trench sidewall oxide thickness. Broadly, gate oxide is deposited in the trench and then removed from the trench along the trench sidewall while leaving gate oxide along the trench bottom, and then gate oxide is is grown in the trench so that the total bottom gate oxide thickness is at least equal to the total sidewall gate oxide thickness. Examples advantageously provide improved performance, including improved ruggedness, with the desirable reverse conduction of SiC MOSFETs, and reduced cost.

In an example, a method of making a trench metal oxide field-effect transistor (MOSFET) may include the operations set forth below. The trench MOSFET may include a volume of silicon carbide semiconductor material. A trench may be created in the volume of silicon carbide semiconductor material, with the trench including a sidewall and a bottom. A gate oxide may be deposited within the trench so that gate oxide is located along at least the bottom and the sidewall of the trench. Gate oxide is removed from the trench along the sidewall, while leaving gate oxide along the bottom. Gate oxide is then grown within the trench, such that an aggregate bottom gate oxide thickness is at least equal to an aggregate sidewall gate oxide thickness.

The preceding example may further include any one or more of the following features.

The operation of growing the gate oxide may involve a thermal oxidation process.

The aggregate bottom thickness of the gate oxide may be approximately between one (1) and two (2) times greater than the aggregate sidewall thickness of the gate oxide.

A nitride structure may be deposited relative to the volume of silicon carbide semiconductor material to mask a subsequent etching operation.

The operation of depositing gate oxide within the trench may include depositing a first bottom thickness of gate oxide along the bottom of the trench and depositing a first sidewall thickness of gate oxide along the sidewall of the trench, and the operation of depositing the nitride structure may include locating the nitride structure within the trench above the first bottom thickness and spaced-apart from the sidewall. The operation of depositing the nitride structure may be performed after the first bottom thickness of gate oxide is deposited but before the first sidewall thickness of gate oxide is deposited. The operations of depositing the first bottom thickness of gate oxide and depositing the first sidewall thickness of gate oxide may alternatively be performed simultaneously, and the operation of depositing the first nitride structure may be performed after the first bottom thickness and first sidewall thickness are deposited. The operation of removing gate oxide may include etching the first sidewall thickness of gate oxide while leaving the first bottom thickness of gate oxide, in which case the nitride structure may be removed before the step of growing the gate oxide. The operation of growing gate oxide within the trench may include growing a second bottom thickness of gate oxide over the first bottom thickness of gate oxide, such that the first and second bottom thicknesses of gate oxide form the aggregate bottom gate oxide thickness, and growing a second sidewall thickness of gate oxide along the sidewall of the trench, such that the second sidewall thickness of gate oxide forms the aggregate sidewall gate oxide thickness. The trench may include a pair of sidewalls and the first sidewall thickness of gate oxide may be deposited along each of the sidewalls, and the operation of locating the nitride structure may include spacing the nitride structure equally between the sidewalls.

The nitride structure may alternatively be located along the first end of the volume of silicon carbide semiconductor material. The method may further include the step of depositing gate oxide over the nitride structure concurrently with deposition of gate oxide within the trench. The method may additionally include the step of removing gate oxide from the nitride structure concurrently with removal of gate oxide from the trench. Yet further, the method may additionally include removing the nitride structure from the first end of the volume of silicon carbide semiconductor material after the steps of removing gate oxide from the trench and the nitride structure but before the step of growing gate oxide within the trench. The trench may include a pair of sidewalls, the first end of the volume of silicon carbide semiconductor material may include split first end segments extending outwardly from the sidewalls of the trench, the operation of depositing the nitride structure may include depositing portions of the nitride structure on the first end segments of the volume of silicon carbide semiconductor material, the operation of depositing gate oxide within the trench may include depositing a first bottom thickness of gate oxide along the bottom of the trench and depositing a first sidewall thickness of gate oxide along each of the sidewalls, the operation of depositing gate oxide over the nitride structure may include depositing gate oxide over the portions of the nitride structure, the operation of removing gate oxide from the trench may include removing the first sidewall thickness of gate oxide from each of the sidewalls while leaving the first bottom thickness of gate oxide, and the operation of removing gate oxide from the nitride structure may include removing gate oxide from the portions of the nitride structure. The step of growing gate oxide within the trench may include growing a second bottom thickness of gate oxide over the first bottom thickness of gate oxide, such that the first and second bottom thicknesses of gate oxide form the aggregate bottom gate oxide thickness, and growing a second sidewall thickness of gate oxide along each of the sidewalls of the trench, such that each of the second sidewall thicknesses forms the aggregate sidewall gate oxide thickness. The step of depositing gate oxide within the trench may include filling the trench with gate oxide between the sidewalls.

The steps of removing gate oxide may involve an anisotropic or isotropic etching process.

The step of depositing gate oxide within the trench includes filling the trench with gate oxide. The method may further include the steps of depositing a nitride structure along the first end of the volume of silicon carbide semiconductor material, depositing gate oxide over the nitride structure concurrently with deposition of gate oxide within the trench, removing gate oxide from the nitride structure concurrently with removal of gate oxide from the trench, and removing the nitride structure from the first end of the volume of silicon carbide semiconductor material after the steps of removing gate oxide from the trench and the nitride structure but before the step of growing gate oxide within the trench.

This summary is not intended to identify essential features of the examples, and is not intended to be used to limit the scope of the claims. These and other aspects of the present examples are described below in greater detail.

### DRAWINGS

Examples are described in detail below with reference to the attached drawing figures, wherein:

FIG. 1 is a cross-sectional elevation view of an example of a trench MOSFET that may be made, in part, using the methods of the present disclosure;

FIG. 2 is a flowchart of operations in an example of a first method of making a trench MOSFET with a trench bottom oxide thickness that is equal to or greater than a trench sidewall oxide thickness;

FIG. 3A is a cross-sectional elevation view of the result of an operation in the method of FIG. 2, showing an etching of a trench;

FIG. 3B is a cross-sectional elevation view of the result of an operation in the method of FIG. 2, showing a deposition of a nitride structure and a first layer of oxide;

FIG. 3C is a cross-sectional elevation view of the result of an operation in the method of FIG. 2, showing an etching of a sidewall portion of the first layer of gate oxide; and

FIG. 3D is a cross-sectional elevation view of the result of an operation in the method of FIG. 2, showing an etching of the nitride structure;

FIG. 3E is a cross-sectional elevation view of the result of an operation in the method of FIG. 2, showing a growth of a second layer of gate oxide;

FIG. 4 is a flowchart of operations in an example of a second method of making a trench MOSFET with a trench bottom oxide thickness that is equal to or greater than a trench sidewall oxide thickness;

FIG. 5A is a cross-sectional elevation view of the result of an operation in the method of FIG. 4, showing an etching of a trench;

FIG. 5B is a cross-sectional elevation view of the result of an operation in the method of FIG. 4, showing a deposition of a first layer of oxide;

FIG. 5C is a cross-sectional elevation view of the result of an operation in the method of FIG. 4, showing an etching of a sidewall portion of the first layer of gate oxide; and

FIG. 5D is a cross-sectional elevation view of the result of an operation in the method of FIG. 4, showing a growth of a second layer of gate oxide.

The figures are not intended to limit the examples to the specific details depict. The drawings are not necessarily to scale.

### DETAILED DESCRIPTION

In the following detailed description, reference is made to the accompanying drawings, which form a part hereof and in which are shown, by way of illustration, specific examples in which the present disclosure may be practiced. These examples are described in sufficient detail to enable a person of ordinary skill in the art to practice the present disclosure. However, other examples may be utilized, and structural, material, procedural, operational, and other changes may be made without departing from the scope of the disclosure. Unless clearly understood or expressly identified otherwise, structures, materials, procedures, operations, and other aspects described in the context of one example may be incorporated into other examples.

The illustrations presented herein are not meant to be actual views of any particular method, system, device, or structure, but are merely idealized representations that are employed to describe the examples of the present disclosure. Similar structures or components in the various drawings may retain the same or similar numbering for the convenience of the reader; however, any similarity in numbering does not necessarily mean that the structures or components are necessarily identical in size, composition, configuration, or any other property. Terms of relative location and direction (e.g., above, below, left, right, upper, lower) may be used to facilitate the present descriptions of examples with reference to the figures, but unless clearly understood or expressly identified otherwise, these terms are not meant to be limiting with regard to location, direction, or overall orientation, and may, for example, change as a result of a change in overall orientation. It will be readily understood that the components of the examples as generally described herein and illustrated in the drawings could be arranged and designed in a wide variety of different configurations. Thus, the following description of various examples is not intended to limit the scope of the present disclosure but is merely representative of various examples.

Generally, gate oxide, which is a dielectric material, such as silicon dioxide (SiO2), that lines the trench of a trench MOSFET, grows thicker at the vertical sidewall plane of the trench and thinner at the horizontal bottom plane of the trench. However, it may be desirable for the final bottom oxide to be at least equal in thickness to the sidewall oxide. A higher voltage on the drain can degrade the oxide at the bottom of the trench, so thicker oxide at that location allows for thinner and narrower shielding which results in a lower drain-to-source “on” resistance (Rds(on)). It is known to use deposited oxide in place of grown, or thermal, oxide, which may avoid this issue, but grown oxide provides a better quality of oxide.

Examples provide a trench MOSFET with a trench bottom oxide thickness that is equal to or greater than a trench sidewall oxide thickness, and a method of making a trench MOSFET with a trench bottom oxide thickness that is equal to or greater than a trench sidewall oxide thickness. The illustrated example broadly involves a trench being created to present a sidewall and a bottom, first sidewall and bottom thicknesses of a gate oxide being deposited, the first sidewall thickness being removed leaving the first bottom thickness, and second sidewall and bottom thicknesses of the gate oxide being grown. The combined first and second bottom thicknesses provide a total bottom thickness of the gate oxide that is at least equal (i.e., equal to or greater than) to the second sidewall thickness of the gate oxide. Examples advantageously provide improved performance, including improved ruggedness, with the desirable reverse conduction of SiC MOSFETs, and reduced cost.

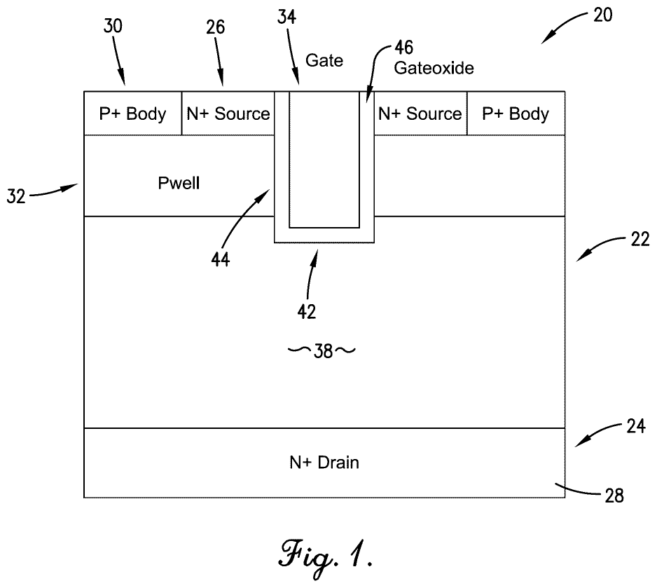

Referring to FIG. 1, an example of a trench MOSFET 20 is shown that may be made, in part, using the first or second methods of the present disclosure to have a trench bottom oxide thickness that is equal to or greater than a trench sidewall oxide thickness. The natures and locations of the MOSFET structures and materials may change from what is described and shown, and may be substantially conventional or unconventional in their formation and operation.

Broadly, the trench MOSFET 20 may include a volume of semiconductor material 22, a doped substrate material 24, a source 26, a drain 28, a body 30, a well 32, a trench 34, and a gate 36. The volume of semiconductor material 22 may include a first end, a second end, a first side, and a second side. The volume of semiconductor material 22 may be constructed from or otherwise include an N-type epitaxial silicon carbide (SiC) semiconductor material.

It will be appreciated that the sides of the illustrated volume of semiconductor material 22 are defined herein merely as an example, and may in various examples represent only a portion of semiconductor material relative to the illustrated MOSFET 20. In practice, the volume of semiconductor may extend laterally (leftward and rightward when viewing FIG. 1) beyond the bounds illustrated in the drawings to present additional semiconductor material in which additional devices may be provided. (The semiconductor material may similarly extend inwardly or outwardly (relative to the lateral or cross-sectional direction depicted in FIG. 1) to present additional devices in a direction transverse to the lateral direction.) Such additional devices may be FETs (which may be similarly or alternatively constructed to the illustrated MOSFET 20) or may be entirely different devices providing different operations or functions than the illustrated MOSFET 20. In other words, in practice, the illustrated MOSFET 20 may be just one of numerous devices spaced laterally and transversely within a single, integrally formed component, such as a wafer (not shown).

The doped substrate material 24 may be located at the second end of the volume of semiconductor material 22, and may be constructed from or otherwise include an N+ substrate material. The source 26 may be located at the first end of the volume of semiconductor material 22 adjacent to the trench 34, may provide an entrance for charge carriers, and may be constructed from or otherwise include an N+ material. The well 32 may include a P material. The drain may be located at the second end of the volume of semiconductor material 22, opposite the source 26, may provide an exit for the charge carriers, and may be provided by the doped substrate material 24. However, according to some aspects of the example MOSFET, the drain may alternatively be located at the first end (same end as the source 26) of the volume of semiconductor material to provide a so-called lateral MOSFET. A channel 38 through which the charge carriers move may extend through a region of the volume of semiconductor material 22 between the source 26 and the drain 28. The body 30 and the P-well 32 may cooperate with the gate 36 to control the movement of charge carriers through the channel 38 between the source 26 and the drain 28. The body 30 may be located adjacent to the source 26 at the first end of the volume of semiconductor material 22, and constructed from or otherwise include a P+material. The P-well may be a P-doped region below the source 26 and the body 30. In this particular example of a FET, the source 26, body 30, and P-well 32 each include left and right instances located on opposite sides of the centrally located trench 34, as shown. These components may be constructed by implanting (using, e.g., an ion implanter) or otherwise introducing appropriate dopants into areas of the volume semiconductor material 22. These components and materials and their sizes and positions may vary depending on the nature of and application for the device.

The trench 34 may be a cavity etched or otherwise created in the volume of semiconductor material 22 at the first end and between the first and second sides. The trench 34 may include a bottom 42, or a horizontal surface, and a sidewall 44, or a vertical surface. The trench is a three-dimensional structure and so may have left, right, front, and back sidewalls, and the term “sidewall,” as used herein may refer to one, some, or all of these vertical surfaces. The trench 34 may be lined with a gate oxide, or dielectric material, (e.g., SiO2) on the bottom 42 and sidewall 44. As discussed, it may be desirable that the thickness of the oxide at the bottom 42, or the bottom oxide thickness, be equal to or greater than the thickness of the oxide at the sidewall 44, or the sidewall oxide thickness.

The gate 36 may cooperate with the body 30 and the P-well 32 to control the movement of charge carriers through the channel 38 between the source 26 and the drain 28. The gate 36 may include a doped polysilicon material 46 deposited or otherwise provided in the oxide-lined trench 34. Electrical terminals (not shown) may be added to the source 26 and body 30, the drain 28, and the gate 36 to facilitate applying appropriate electrical voltages for operation of the MOSFET 20.

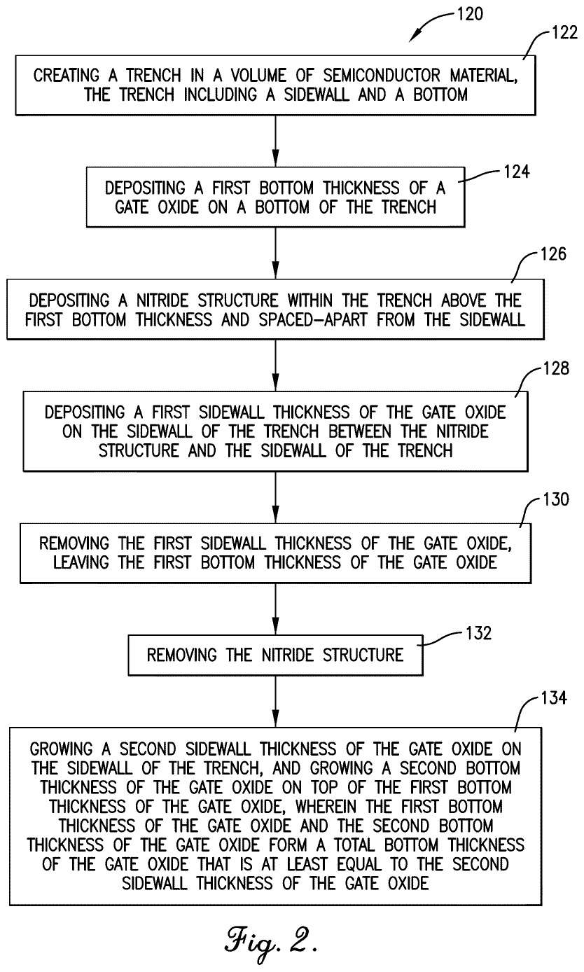

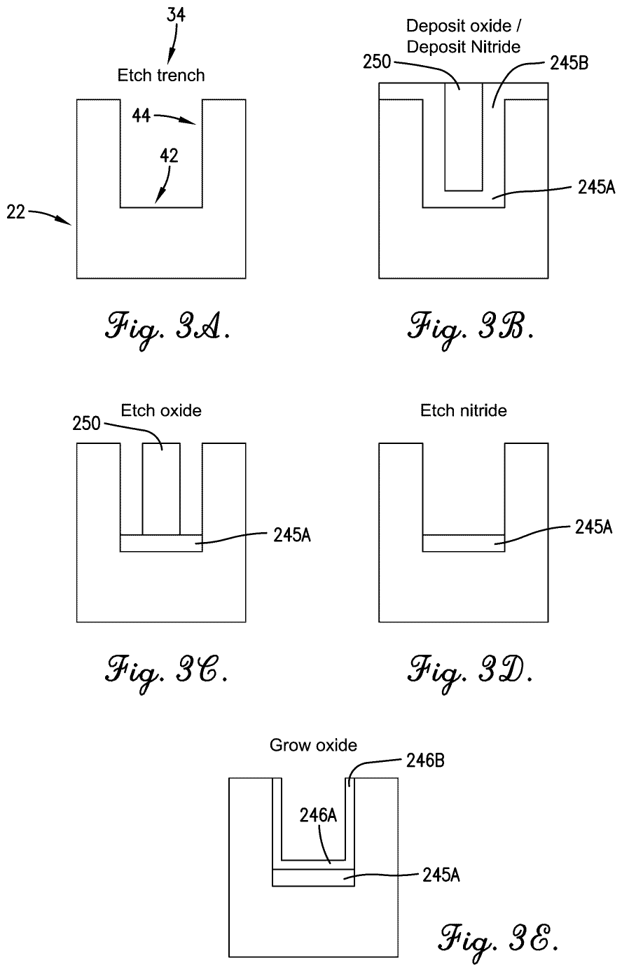

Referring to FIG. 2 an example of a first method 120 of making a trench MOSFET, such as the trench MOSFET 20 described above, with a trench bottom oxide thickness that is equal to or greater than a trench sidewall oxide thickness, may include the operations set forth below. Other structures of the trench MOSFET 20, including those described above and shown in FIG. 1, may be made using otherwise substantially conventional or unconventional techniques which are described elsewhere. Referring additionally to FIGS. 3A-E, example results of at least some of the operations of the first method 120 are shown.

The trench 34 may be etched or otherwise created in the first end of the volume of semiconductor material 22, as shown in 122 and seen in FIG. 3A. The trench 34 may include the bottom 42 and the sidewall 44. A first bottom thickness 245A of the gate oxide 46 may be deposited on the bottom 42 of the trench 34, as shown in 124 and seen in FIG. 3B. A nitride structure 250 may be deposited or otherwise provided within the trench 34 above the first bottom thickness 245A of the gate oxide and spaced-apart from the sidewall 44, as shown in 126 and seen in FIG. 3B. A first sidewall thickness 245B of the gate oxide may be deposited on the sidewall 44 of the trench 34 between the nitride structure 250 and the sidewall 44 of the trench 34, as shown in 128 and seen in FIG. 3B. This results in a first sidewall thickness 245B of the gate oxide and a first bottom thickness 245A of the gate oxide, and because these first thicknesses are deposited rather than grown, the first sidewall thickness 245B and the first bottom thickness 245A may be approximately equal.

The first sidewall thickness 245B of the gate oxide may be etched or otherwise removed, as shown in 130 and seen in FIG. 3C, leaving the first bottom thickness 245A of the gate oxide. The remaining thickness of the first bottom thickness 245A may depend on the desired final result. If it is desirable to ultimately have the same total thickness of the gate oxide 46 at the bottom 42 as at the sidewall 44, then the thickness of the remaining first bottom thickness 245A of the gate oxide should be sufficient to make up for the difference in thicknesses resulting from the subsequent step involving growing a second layer of the gate oxide at the sidewall 44 and the bottom 42. If it is desirable to ultimately have thicker total gate oxide 46 at the bottom 42 than at the sidewall 44, then the thickness of the remaining first bottom thickness 245A of the gate oxide may be something more than sufficient to make up for the difference in thicknesses resulting from the subsequent step involving growing a second layer of the gate oxide at the sidewall 44 and the bottom 42. Because the nitride structure 250 shields the first bottom thickness, the first sidewall thickness may be removed by isotropic (non-directional) or anisotropic (directional, or, in this case, vertical) etching.

The nitride structure 250 may be etched or otherwise removed, as shown in 132 and seen in FIG. 3D. A second sidewall thickness 246B of the gate oxide may be grown on the sidewall 44 of the trench 34, and a second bottom thickness 246A of the gate oxide may be grown below the first bottom thickness 245A of the gate oxide (i.e., at the SiC interface), as shown in 134 and seen in FIG. 3E. The second thicknesses of the gate oxide 246A, 246B may be grown using, e.g., thermal oxidation. Thermal oxidation may involve implanting or depositing silicon (Si) (using, e.g., an ion implanter) into the volume of semiconductor material 22 at the sidewall 44 and the bottom 42 of the trench 34, and then oxidizing the Si (using, e.g., thermal oxidation) in situ.

Because the second thicknesses are grown rather than deposited, the second sidewall thickness 246B may be greater than the second bottom thickness 246A. However, because the second bottom thickness 246A is added below the first bottom thickness 245A, the resulting total bottom thickness 245A, 246A of the gate oxide may be, as desired, equal to or greater than the total sidewall thickness 246B of the gate oxide. For example, the total bottom thickness 245A, 246A of the gate oxide may be approximately between one (1) and two (2) times greater than the total thickness 246B of the gate oxide. Additional processing may occur as desired, such as using masks to protect surfaces and planarizing to smooth surfaces.

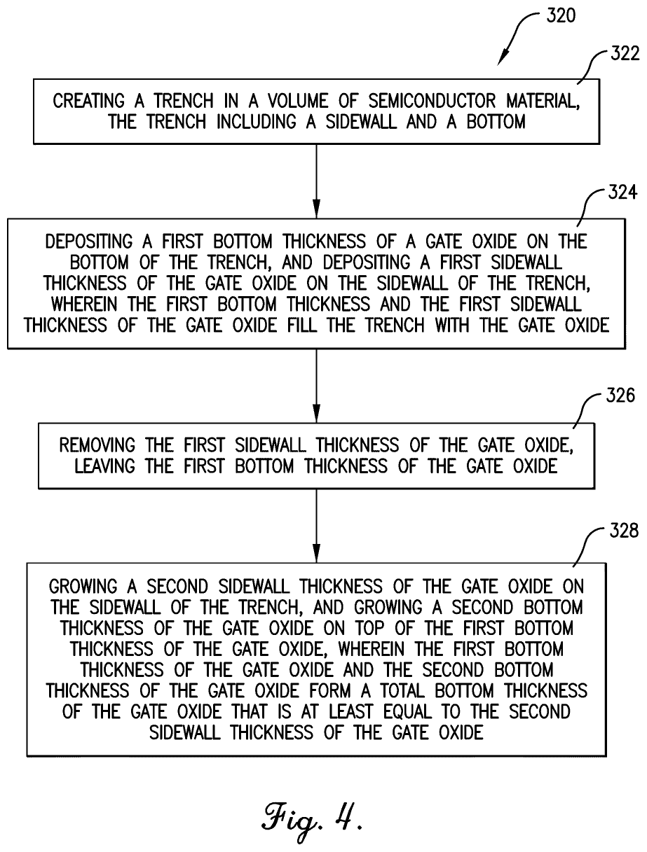

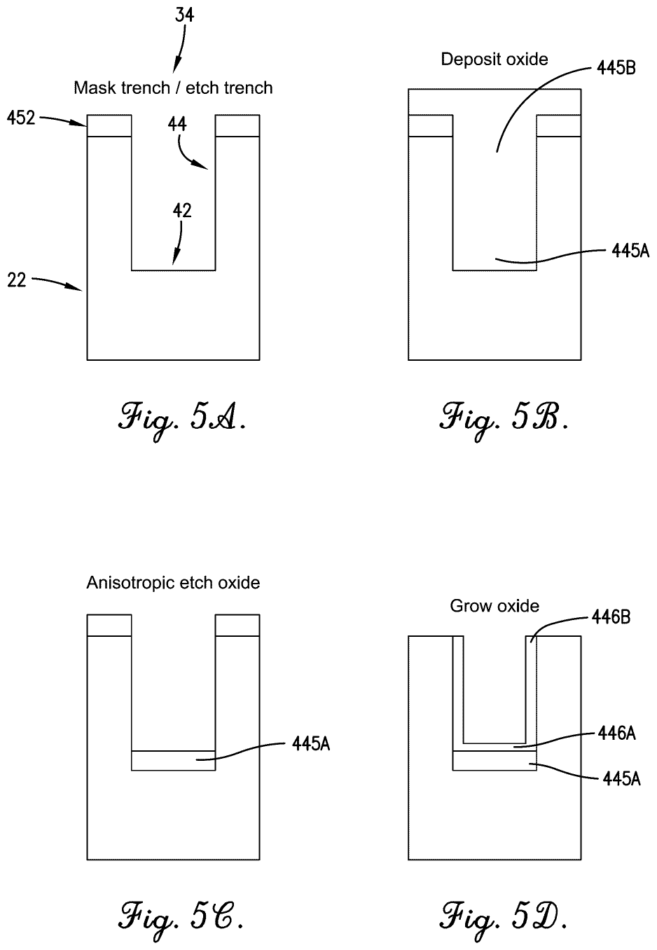

Referring to FIG. 4 an example of a second method 320 of making a trench MOSFET, such as the trench MOSFET 20 described above, with a trench bottom oxide thickness that is equal to or greater than a trench sidewall oxide thickness, may include the operations set forth below. Other structures of the trench MOSFET 20, including those described above and shown in FIG. 1, may be made using otherwise substantially conventional or unconventional techniques which are described elsewhere. Referring additionally to FIGS. 5A-D, example results of at least some of the operations of the second method 320 are shown.

The trench 34 may be etched or otherwise created in the volume of semiconductor material 22, as shown in 322 and seen in FIG. 5A. Prior to etching, a mask 452 may be applied to limit the action of the etchant to the desired area. The trench 34 may include the sidewall 36 and the bottom 38. A first bottom thickness 445A of a gate oxide may be deposited on the bottom 42 of the trench 34, and a first sidewall thickness 445B of the gate oxide may be deposited on the sidewall 44 of the trench 34, wherein the first bottom thickness 445A and the first sidewall thickness 445B fill the trench with the gate oxide, as shown in 324 and seen in FIG. 5B.

The first sidewall thickness 445B of the gate oxide may be etched or otherwise removed, as shown in 326 and seen in FIG. 5C, leaving only a remaining part of the first bottom thickness 445A of the gate oxide. The thickness of the remaining first bottom thickness 445A of the gate oxide may depend on the desired final result. If it is desirable to ultimately have the same total thickness of the gate oxide 46 at the bottom 42 as at the sidewall 44, then the remaining first bottom thickness 445A of the gate oxide should be sufficient to make up for the difference in thicknesses resulting from the subsequent step involving growing a second layer of the gate oxide at the sidewall 44 and the bottom 42. If it is desirable to ultimately have thicker gate oxide 46 at the bottom 42 than at the sidewall 44, then the remaining first bottom thickness 445A of the gate oxide should be something more than sufficient to make up for the difference in thicknesses resulting from the subsequent step involving growing a second layer of the gate oxide at the sidewall 44 and the bottom 42. If the trench 34 is relatively narrow, the first sidewall thickness 445B may be removed by isotropic (non-directional) etching. Otherwise, it may be preferable to remove the first sidewall thickness 445B by anisotropic (directional, or, in this case, vertical) etching.

A second sidewall thickness 446B of the gate oxide may be grown on the sidewall 44 of the trench 34, and a second bottom thickness 446A of the gate oxide may be grown below the first bottom thickness 445A of the gate oxide (i.e., at the SiC interface), as shown in 328 and seen in FIG. 5D. The second thicknesses of the gate oxide may be grown using, e.g., thermal oxidation (which is described above). Because the second thicknesses are grown rather than deposited, the second sidewall thickness 446B may be greater than the second bottom thickness 446A. However, because the second bottom thickness 446A is added below the first bottom thickness 445A of the gate oxide, the resulting total bottom thickness 445A, 446A of the gate oxide may be, as desired, at least equal to the second sidewall thickness 446B of the gate oxide. For example, the total bottom thickness 445A, 446A of the gate oxide at the bottom 42 of the trench 34 may be approximately between one (1) and two (2) times greater than the total thickness 446B of the gate oxide at the sidewall 44 of the trench 34. Additional processing may occur as desired, such as using masks to protect surfaces and planarizing to smooth surfaces.

Although described herein with regard or in relation to one or more particular kinds of electronic devices (e.g., junction field-effect transistors, metal oxide semiconductor field-effect transistors), the technology may be more broadly applicable to one or more other kinds of electronic devices as well. One with ordinary skill in the art will recognize that the technology described herein may, when applicable, be implemented in enhancement mode or depletion mode. Further, the technology described herein may, when applicable, be implemented as an N-channel or P-channel device, wherein, in general, regions that are N-doped or P-doped in N-channel implementations may be, respectively, P-doped or N-doped in P-channel implementations. Additionally, the various example materials identified herein may, in some aspects, be replaced or supplemented with substantially any other suitable material. For example, gate material may include polysilicon, a metal or alloy of metals, or other suitable material; gate oxide or dielectric may include silicon dioxide, aluminum oxide, hafnium dioxide, silicon nitride, or other suitable material; and semiconductor material may include silicon carbide, gallium nitride, zinc oxide, or other suitable material.

Additionally, in general, unless otherwise specified or unless one with ordinary skill in the art would understand otherwise, doping concentrations for contact implants may be approximately between 10~and 1×10\hat{ }22; doping concentrations for channel and threshold forming implants may be approximately between 10\hat{ }16 and 10\hat{ }17; doping concentrations for shielding implants may be approximately between 10\hat{ }17 and 10\hat{ }19; and doping concentrations for conductivity improvement implants (e.g., N-doping in the junction field-effect transistor neck region of a metal oxide semiconductor field-effect transistor) may be approximately between 10\hat{ }16 and 10\hat{ }17. Relatedly, a structure or region may contain two or more different doping doses. For example, one with ordinary skill in the art will recognize that some P-wells may contain a lower dose P-well portion and a higher dose unclamped inductive switching portion.

While the present disclosure has been described herein with respect to certain illustrated examples, those of ordinary skill in the art will recognize and appreciate that the present disclosure is not so limited. Rather, many additions, deletions, and modifications to the illustrated and described examples may be made without departing from the scope of the disclosure as hereinafter claimed along with their legal equivalents. In addition, features from one example may be combined with features of another example while still being encompassed within the scope of the disclosure as contemplated by the inventors.

1. A method of making a trench metal oxide field-effect transistor (MOSFET), the trench MOSFET including a volume of silicon carbide semiconductor material, the method comprising:
creating a trench in the volume of silicon carbide semiconductor material, the trench including a sidewall and a bottom;
depositing gate oxide within the trench so that gate oxide is located along at least the bottom and the sidewall of the trench;
removing gate oxide from the trench along the sidewall, while leaving gate oxide along the bottom; and
growing gate oxide within the trench, such that an aggregate bottom gate oxide thickness is at least equal to an aggregate sidewall gate oxide thickness.

2. The method of claim 1, wherein the step of growing gate oxide involves a thermal oxidation process.

3. The method of claim 1, wherein the aggregate bottom gate oxide thickness oxide is between one (1) and two (2) times greater than the aggregate second sidewall thickness of the gate oxide.

4. The method of claim 1, further comprising:
depositing a nitride structure relative to the volume of silicon carbide semiconductor material to mask a subsequent etching operation.

5. The method of claim 4, wherein the step of depositing gate oxide within the trench includes depositing a first bottom thickness of gate oxide along the bottom of the trench and depositing a first sidewall thickness of gate oxide along the sidewall of the trench, and wherein the step of depositing the nitride structure includes the step of locating the nitride structure within the trench above the first bottom thickness and spaced-apart from the sidewall.

6. The method of claim 5, wherein the step of depositing the nitride structure is performed after the first bottom thickness of gate oxide is deposited but before the first sidewall thickness of gate oxide is deposited.

7. The method of claim 5, wherein the steps of depositing the first bottom thickness of gate oxide and depositing the first sidewall thickness of gate oxide are performed simultaneously, and the step of depositing the first nitride structure is performed after the first bottom thickness and first sidewall thickness are deposited.

8. The method of claim 5, wherein the step of removing gate oxide includes the step of etching the first sidewall thickness of gate oxide, while leaving the first bottom thickness of gate oxide, and removing the nitride structure before the step of growing the gate oxide.

9. The method of claim 5, wherein the step of growing gate oxide within the trench includes growing a second bottom thickness of gate oxide under the first bottom thickness of gate oxide, such that the first and second bottom thicknesses of gate oxide form the aggregate bottom gate oxide thickness, and growing a second sidewall thickness of gate oxide along the sidewall of the trench, such that the second sidewall thickness of gate oxide forms the aggregate sidewall gate oxide thickness.

10. The method of claim 5, wherein the trench includes a pair of sidewalls and the first sidewall thickness of gate oxide is deposited along each of the sidewalls, and wherein the step of locating the nitride structure includes spacing the nitride structure equally between the sidewalls.

11. The method of claim 4, wherein the trench extends from a first end of the volume of silicon carbide semiconductor material, and wherein the step of depositing the nitride structure includes the step of locating the nitride structure along the first end.

12. The method of claim 11, further comprising:
depositing gate oxide over the nitride structure concurrently with deposition of gate oxide within the trench.

13. The method of claim 12, further comprising:
removing gate oxide from the nitride structure concurrently with removal of gate oxide from the trench.

14. The method of claim 13, further comprising:
removing the nitride structure from the first end of the volume of silicon carbide semiconductor material after the steps of removing gate oxide from the trench and the nitride structure but before the step of growing gate oxide within the trench.

15. The method of claim 13,
the trench including a pair of sidewalls,
the first end of the volume of silicon carbide semiconductor material including split first end segments extending outwardly from the sidewalls of the trench,
the step of depositing gate oxide within the trench including depositing a first bottom thickness of gate oxide along the bottom of the trench and depositing a first sidewall thickness of gate oxide along each of the sidewalls,
the step of depositing the nitride structure including depositing portions of the nitride structure on the first end segments of the volume of silicon carbide semiconductor material,
the step of depositing gate oxide over the nitride structure including depositing gate oxide over the portions of the nitride structure,
the step of removing gate oxide from the trench including removing the first sidewall thickness of gate oxide from each of the sidewalls, while leaving the first bottom thickness of gate oxide,
the step of removing gate oxide from the nitride structure including the step of removing gate oxide from the portions of the nitride structure.

16. The method of claim 15, wherein the steps of removing gate oxide involve an anisotropic etching process.

17. The method of claim 15, wherein the step of growing gate oxide within the trench includes growing a second bottom thickness of gate oxide under the first bottom thickness of gate oxide, such that the first and second bottom thicknesses of gate oxide form the aggregate bottom gate oxide thickness, and growing a second sidewall thickness of gate oxide along each of the sidewalls of the trench, such that each of the second sidewall thicknesses forms the aggregate sidewall gate oxide thickness.

18. The method of claim 16, wherein the step of depositing gate oxide within the trench includes filling the trench with gate oxide between the sidewalls.

19. The method of claim 1, wherein the step of depositing gate oxide within the trench includes filling the trench with gate oxide.

20. The method of claim 19,
the trench extending from a first end of the volume of silicon carbide semiconductor material;
depositing a nitride structure along the first end of the volume of silicon carbide semiconductor material;
depositing gate oxide over the nitride structure concurrently with deposition of gate oxide within the trench;
removing gate oxide from the nitride structure concurrently with removal of gate oxide from the trench; and
removing the nitride structure from the first end of the volume of silicon carbide semiconductor material after the steps of removing gate oxide from the trench and the nitride structure but before the step of growing gate oxide within the trench.
